(19) United States
(12) Patent Application Publication
(10) Pub. No.: US 2008/0272853 A1
(43) Pub. Date: Nov. 6, 2008

(54) Filter That Comprises Bulk Acoustic Wave Resonators And That Can Be Operated Symmetrically On Both Ends

(76) Inventors: Habbo Heinze, Munich (DE); Edgar Schmidhammer, Stein (DE); Pasi Tikka, Unterchaching (DE)

Correspondence Address: FISH & RICHARDSON PC, P.O. BOX 1022, MINNEAPOLIS, MN, 55440-1022, US

(21) Appl. No.: 11/631,710

(22) PCT Filed: Jun. 3, 2005
(86) PCT No.: PCT/EP05/05998

§ 371 Date: Jul. 26, 2007

(30) Foreign Application Priority Data
Jul. 7, 2004 (DE) 10 2004 032 930.0

(51) Int. Cl. H03H 9/60; H03H 7/38

(52) U.S. Cl. 333/129; 333/32; 333/133

(57) ABSTRACT

A filter for use with bulk acoustic waves includes an input port and an output port. The input port and the output port are symmetrically operable. Signal paths extend from a terminal of the input port to a terminal of the output port. Bulk acoustic wave resonators are in the signal pats. The bulk acoustic wave resonators are arranged symmetrically in the signal paths. A complex impedance associated with each signal path is provided for electrically matching to a corresponding connection.

### BACKGROUND

The efficiency of modern mobile radio systems is essentially dependent on the quality of the filters required for signal processing. Particularly for bandpass filters, a number of requirements must be fulfilled, which can be different and are specified by the individual mobile radio system or the standard.

Bandpass filters can be implemented by different techniques. For example, filters which are constructed from discrete LC elements are known. Furthermore, microwave-ceramic resonators are known. Particularly far developed and greatly varied with regard to the characteristics thereby attainable are filters which work with surface acoustic wave filters, so-called SAW filters.

More recent developments show that filters working with bulk acoustic waves, which are built from bulk acoustic wave resonators, also have considerable technical potential, which can make them a preferred filtering technique.

In addition to the pure transfer behavior of a filter, which can be seen with the aid of the transfer curve, usually shown as S-parameters of the scattering matrix, other electrical functions can also be integrated in a filter, for example, the reshaping of an asymmetrical (single-ended) signal into a symmetrical or balanced signal. It is also possible to perform, in the filter itself, an impedance transformation between the filter input and output.

In general, for the optimal functioning of a filter, the electrical and circuit-engineering environment in which the filter is used is important. The form in which the signal to be filtered appears at the filter input, whether asymmetrical or symmetrical, is also important, as is how the filtered signal at the filter output is passed on to the next processing stage of a system or what is required by the next stage. Filters with asymmetrical filter inputs and outputs, which therefore process a single “hot” or information-carrying potential that is always referenced to ground, can be produced in a completely nonproblematic manner.

It is more difficult to convert such asymmetrical signals into symmetrical ones—or even to process a symmetrical signal and also again make it available symmetrically at the output. Such filters, which are operated balanced on both ends, are to be implemented, only with difficulty, with filters which work with bulk acoustic waves.

Prior art filters that comprise bulk acoustic wave resonators and that can be operated symmetrically on both ends primarily exhibit unsatisfactory filter behavior in the passband, which has excessively high ripple, whereby the insertion loss suffers and the filtering behavior is disturbed.

### SUMMARY

Described herein is a filter which can be operated symmetrically on both ends, with bulk acoustic wave resonators, which is improved with regard to its filter behavior, especially in the passband.

The filter is constructed from bulk acoustic wave resonators. It has an electric input port and an electric output port, both of which can be operated symmetrically. Accordingly, the filter has two signal paths, which extend from a terminal of the input port to a terminal of the output port. With regard to these signal paths, the bulk acoustic wave resonators are located electrically symmetrically to one another. Each of the two signal paths is connected to a complex impedance.

Substantially improved transfer characteristics are obtained with the filter described herein in comparison to known symmetrical filters operating with bulk waves. In particular, the filter has a smoothed passband, which, in comparison with prior art filters, has less insertion loss. In an alternative representation, the filter has substantially smaller deviations from the optimal matching point in the Smith chart and behaves well in the optimal range. Thus, the filter exhibits optimal electrical matching, which later leads to reduced insertion loss, to lower ripple, and to an improved filter behavior. By varying the complex impedances, it is possible to adapt the filter optimally to any external environment.

Herein, “complex impedance” is understood to mean not only an individual, actual circuit element having an impedance, but also a combination of ideal, actual, individual components affected by an impedance.

The bulk acoustic wave resonators can be individual acoustic wave oscillators. The bulk acoustic wave resonators, however, can also be thin-film resonators. The entire filter is may be an integrated arrangement of thin-film resonators, in which the individual thin-film resonators and their wiring are constructed in an integrated manner during the fabrication process. In one embodiment, all bulk acoustic wave resonators are placed on a single, common substrate. However, the construction of the filter components on different substrates and their suitable interconnections are also possible.

Every signal path is connected to at least one complex impedance. Connection to the filter can take place on one or both electric ports. This does not rule out that, within the filter, other complex impedances are connected to other connecting sites, which produces other advantages.

In one embodiment, each terminal of each port is connected to another complex impedance.

In another embodiment, each signal path is connected in series with a complex impedance, so that this impedance is pad of the individual signal path. In another embodiment, the two signal paths are connected in parallel with a complex impedance. The impedance can thereby be located in a transverse branch, which connects the two signal paths.

The filter can also be designed as a reactance network of resonators. The resonators can be placed in series and parallel branches. In these cases, it is also possible to provide the complex impedance in one of the parallel branches that bridge the two signal paths.

Another embodiment connects two terminals of one port in series with a complex impedance, but with the two terminals of the other port connected in parallel with another complex impedance. With regard to the different types of connections of complex to impedances with the signal paths as implemented in a filter, the already mentioned variation possibilities are valid for each of the two possibilities.

The bulk acoustic wave resonators can be connected in a ladder-type arrangement. It is also possible to connect the bulk acoustic wave resonators in a lattice arrangement. A filter which saves space in particular or which can operate with few bulk acoustic wave resonators utilizes bulk acoustic wave resonators in a stacked arrangement, which is designated as a CRF arrangement (Coupled Resonator Filter). Such CRF filters comprise thin-film resonators formed in a stack, one above another, wherein resonators which are adjacent in a stack can have a common middle electrode. It is also possible, however, to provide a coupling layer between the two thin-film resonators arranged one above the other. The fraction of the acoustic coupling between the first and second resonators arranged one above the other is determined as a function of the thickness and the material of the coupling layer. Such a filter, comprised only two stacked thin-film resonators acoustically coupled to one another, can be operated symmetrically on both ends.

A filter in accordance with this disclosure can also comprise two partial arrangements of bulk acoustic wave resonators, connected in series with one another. Each of the partial arrangements, independently of one another, corresponds to the already mentioned types of bulk acoustic wave resonator filter arrangements. For the connection, a first port of the first partial arrangement is connected to a second port of the second arrangement. It is also thereby possible to provide complex impedances between the two partial arrangements within the framework of the connection.

In one embodiment, the complex impedance comprises an inductor. Such an inductor can be produced in a particularly simple manner and can be implemented as a function of the required inductor value, for example, in the form of simple printed conductors, electrical connections, and also bumps. Larger inductors are produced in the form of coils or meandering sections of printed conductors, which can also be included as integrated passive components

In one embodiment, the bulk acoustic wave resonators of the filter are placed on a common substrate; the substrate, in turn, is affixed to a multilayer carrier. In the multilayer carrier, connection structures and passive components are provided which can comprise complex impedances and, moreover, other connection elements. In this way, a particularly compact components is obtained, which, has no other discrete component aside from the thin-film resonator arrangement on the substrate. In this component, all other required passive components are integrated into the carrier or, if necessary, also into the substrate of the thin-film resonator arrangement.

If the substrate on which the bulk acoustic wave resonators are located is constructed from a semiconductor, then the complex impedances can also be implemented, at least in part, integrated in the semiconductor substrate. In a known manner, all connection structures and passive and active components can also be implemented in the semiconductor.

For the exact shaping and dimensioning of the complex impedance, specifically, the impedance which comprises an inductor, the exact connection of the impedance is decisive. For a series-connected impedance, for example, an inductor in the range of 0.1 to 10 nH is selected. An impedance connected in parallel can, for example, be constructed with an inductor in the range of 10-100 nH, in order to achieve optimal matching to an external connection environment.

Optimally matched filters that can be symmetrically operated on both ends have the additional advantage, aside from the improved filter characteristics, that they behave without problems in connections with other filters which can also be operated balanced/balanced, and there is almost no mutual influence between the two filters, as long as they work in different frequency bands. This is possible since, in the Smith diagram, the range of the individual passbands of filters assumes only a small area, which is equivalent to excellent matching. Thus, for example, with an input-side diplexer, only very few additional elements are still required.

On the basis of the good connectability with other similarly designed filters, filter banks can be implemented in this way, for example, cascaded arrangements of diplexers, wherein the two individual filters of the diplexer of such a cascade, standing hierarchically at the very top, can be firmly connected with a common terminal. The signal is then made available, in accordance with its wavelength of the corresponding filter, to the hierarchically lowest stage on the output port.

Embodiments are explained in more detail below with the aid of examples and corresponding figures. The figures are used solely for better understanding and are therefore only drawn schematically and not true to scale. Similar or similarly operating parts are provided with the same reference symbols.

### DESCRIPTION OF THE DRAWINGS

FIG. 1 shows a known symmetrical filter.

FIG. 2 shows the passband of this filter.

FIG. 3 shows the Smith chart for the known filter.

FIG. 4 shows various filters.

FIG. 5 shows components of filters.

FIG. 6 shows possible developments of filters.

FIG. 7 shows the passband and the Smith chart of another filter.

FIG. 8 shows the passband and the Smith chart of another filter.

FIG. 9 shows a diplexer, which is designed with two filters and generally cascaded structures.

FIG. 10 shows a filter affixed to a substrate with an integrated complex impedance.

### DETAILED DESCRIPTION

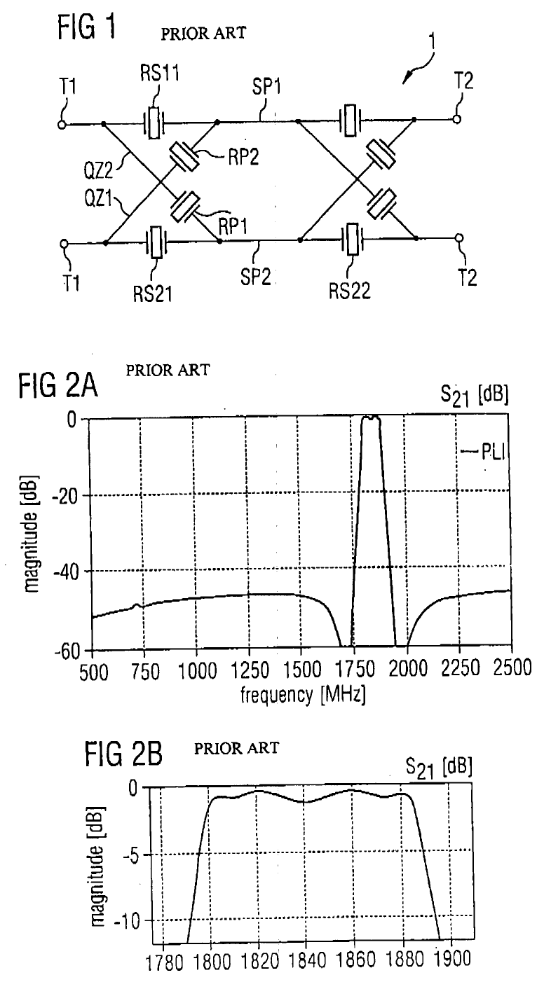

FIG. 1 shows a filter, by way of example, which is known from EP1 017 170 A2 and which comprises an arrangement of bulk acoustic wave resonators RS, RP, which is symmetrical with regard to the signal paths SP1 and SP2. The two signal paths SP1, SP2 connect the two terminals of a first port T1 to the two terminals of a second port T2. If, for example, a symmetrical signal whose two components of the same amplitude have a phase difference of 180° is input to the first port T1, then the filtered signals are output symmetrically with an optimal phase difference of 180° and the same amplitude at the second port T2. The bulk acoustic wave resonators are connected in a lattice arrangement and comprise series resonators RS arranged in the signal paths and parallel resonators RP arranged in transverse branches QZ, which connect the series pats SP to one another. A basic element of a lattice arrangement includes one series resonator RS1, 1, RS2, 1 in each of the two signal paths SP and two intersecting transverse branches QZ1, QZ2, in which, likewise, one parallel resonator RP1, RP2 is located. The known filter 1 has two basic elements here.

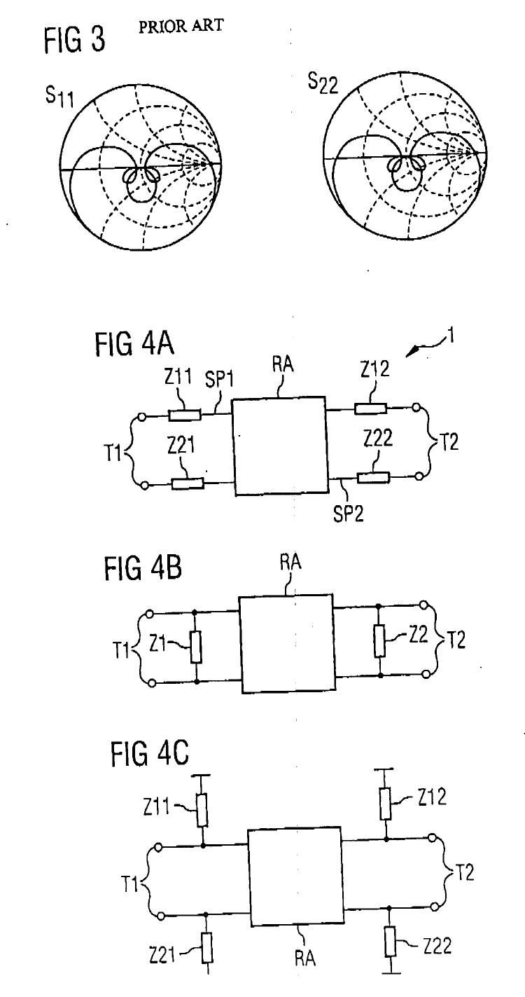

If one implements a GSM filter, adapted to 100 Ohms, with such an arrangement, then one obtains the transfer curve whose frequency parameters are shown in FIG. 2. FIG. 2A shows the entire range for the parameter S2, 1, whereas FIG. 2B shows a part of the range of the passband in an enlarged representation. One can clearly see that the known filter, in spite of the optimization, has a high ripple content in the passband, and in the middle of the passband, a pronounced discontinuity, a so-called DIP, which is responsible for poor filter characteristics and moderate insertion loss. FIG. 3 shows the Smith charts for the two scatter parameters S11 and S22, where, with the aid of the relatively large rings in the middle of the chart, the poor filter characteristics and the poor matching can be seen.

FIG. 4, on the other hand, shows different embodiments for a filter with substantially improved filter characteristics in comparison to the known filters shown in FIGS. 1 to 3.

FIG. 4A shows a first embodiment with a resonator arrangement RA, which is connected to a first port T1 and a second port T2. The connection of the two ports T via the resonator arrangement takes place via two signal paths SP1, SP2, in which bulk acoustic wave resonators are arranged. Each of the two signal paths is also connected to an impedance Z, which is located here between the resonator arrangement RA and the individual port. FIG. 4A shows an embodiment in which four complex impedances Z11, Z12, Z21, Z22 are connected in series with the resonator arrangement RA.

FIG. 4B shows a second arrangement, in which likewise two ports T1, T2, with a resonator arrangement RA of bulk acoustic wave resonators, are connected via two signal paths SP. The two signal paths are connected in the area of the two ports to a complex impedance Z1, Z2, which, however, are connected to the signal paths in parallel. FIG. 4B shows an embodiment in which the complex impedances are located in a transverse branch which connects the two signal paths in the area of the port.

FIG. 4C shows another embodiment: here, four complex impedances Z11, Z12, Z21, Z22 are connected in parallel to the signal paths via a ground terminal.

With the aid of the complex impedances, which are connected with the arrangement of bulk acoustic wave resonators, a substantial improvement is attained both in the passband and in the electrical matching of the filter. The improvements can be seen, for example, in the passband, which has reduced ripple and also no discontinuity in the middle. Smaller “rings” are observed in the Smith chart.

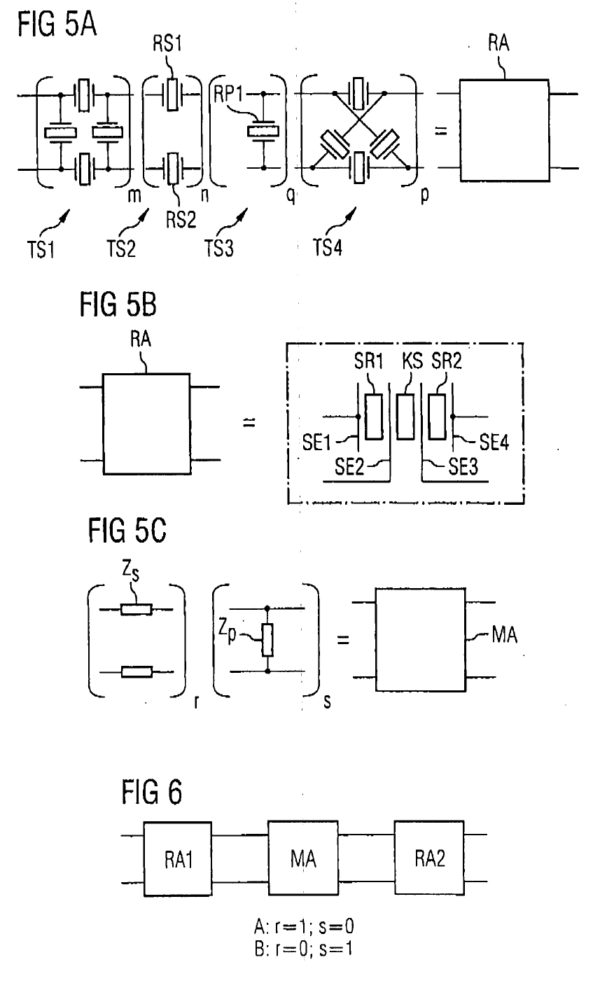

FIG. 5A shows, in a generalized summary form, a resonator arrangement RA, as it can be used in filters. The resonator arrangement IRA can, for example, comprise four different substructures TS1, TS2, TS3, and TS4, which can be connected in arbitrary sequence and a subcombination behind one another in such a way that two symmetrical signal paths are produced. Each of the substructures TS can appear several times, wherein the index m, the number of the first substructure TS1, which is designed as a ladder-type structure, and the index p for the third structure TS3, designed as a lattice arrangement, can assume values of 0 to about 100, independently of one another. It holds for a filter that the sum (m+n+p+q) must be greater than or equal to 1. The second substructure TS2 comprises a pair of series bulk acoustic wave resonators RS1, RS2, for whose index n the following is valid: 0 is less than or equal to n is less than or equal to 100. The third substructure TS3 contains a parallel resonator RP1. A resonator arrangement which can be used for filters, therefore, can comprise both the same as well as different substructures, which can be combined with one another in arbitrary number and sequence.

Good characteristics for a filter are already obtained, however, with one or two substructures.

FIG. 5B shows another embodiment of a resonator arrangement. The resonator arrangement comprises a stack of bulk acoustic wave resonators acoustically coupled to one another, a so-called CRF filter (Coupled Resonator Filter), in which a first stacked resonator SR1 and a second stacked resonator SR2 are arranged one above the other, between two electrode layers SE1, SE2, and SE3, SE4, respectively, wherein a coupling layer KS is located between the first and second stacked resonators, with the material and the thickness of the coupling layer determining the degree of coupling between the two stacked resonators SR1, SR2. Also, this resonator arrangement RA can be operated symmetrically if the two electrodes SE1 and SE2 of the first stacked resonator SR1 are connected symmetrically to the first port and the two electrodes SE3, SE4 of the second stacked resonator SR2 are connected symmetrically to the second port.

Such a resonator arrangement can also be cascaded, i.e., the arrangement is connected repeatedly in series, one component behind another. The resonator arrangement RA, designed as a CRF, may be designed on a substrate with large surface area in the form of thin-film resonators.

FIG. 5C shows different arrangements of complex impedances, which can be made as series or parallel impedances, Zₛ, Zₚ. As with the resonator arrangement, the subunits can also appear in arbitrary number and sequence, where r indicates the number of series units and s the number of parallel units. Together, the complex impedance is produced with the arbitrary variation of r and s between 0 and 100. Since the impedances are always present symmetrically or are located symmetrically in the filter, such a composed, complex impedance is shown below also in general notation as a matching unit MA.

FIG. 6 shows, in general notation, various possibilities of how to connect two resonator arrangements RA1, RA2 together using an intermediate connection of complex impedances Z or the formed matching unit MA and how they can be a part of filters. In principle, one can distinguish between case A and case B. In case A, two resonator arrangements RA1, RA2 are connected via series impedances Z1, Z2, in a signal path between the two resonator arrangements. For this case, r=1 and s=0. In case B, two resonator arrangements RA1, RA2 are connected via a parallel impedance Z in a transverse branch between the signal paths and between the two resonator arrangements, this case, r=0 and s=1.

The connections shown in FIG. 6 can also be connected with the embodiments shown in FIG. 4. In this manner, the variation diversity of resonator arrangements is further increased, wherein in the individual case, advantageous characteristics of such developments can be obtained.

A filter in accordance with this disclosure generally possesses a symmetrical arrangement of resonators and of impedances Z. The symmetry thereby specifically refers to the two signal paths in which the arrangement is developed symmetrically, relative to one another. Moreover, the symmetry can also refer to the two ports T1, T2, so that the connection of the first port T1 can be symmetric to the connection of the second port T2. It is also possible, however, to undertake a connection with impedances on the first port T1 different from that on the second port T1 and, for example, to combine series impedances on the first port with parallel impedances on the second port.

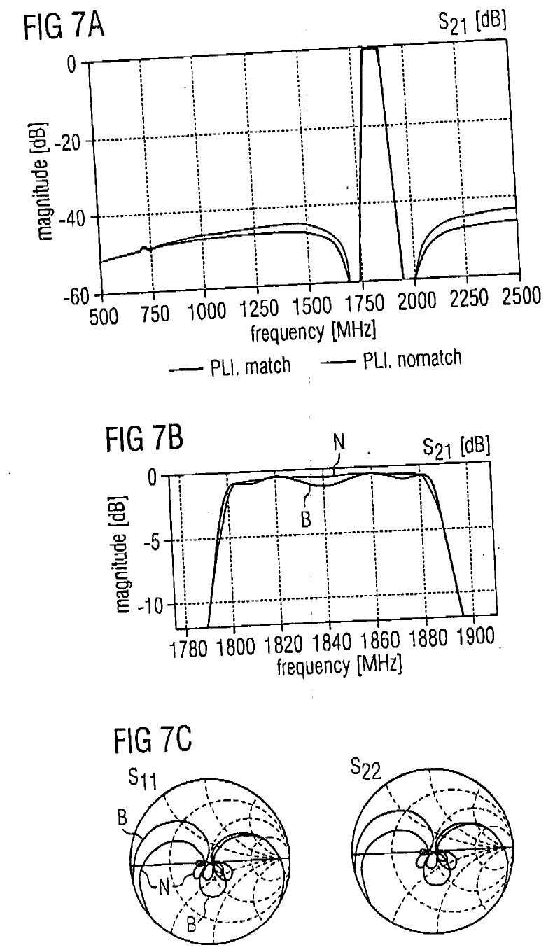

FIG. 7 shows, by way of example, the improvement regarding the filter behavior attained herein, with the aid of the scatter parameters S11 and S22. The passband of a filter is represented in FIGS. 7A and 7B, as the course of the scatter parameter S21. FIG. 7C shows the corresponding Smith charts. The characteristics of a filter designed according to FIG. 4A are shown, in which the resonator arrangement is designed according to FIG. 5, wherein the parameter m is set equal to n equal to 0 and p equal to 2. In the diagrams of FIG. 7, a curve B, which corresponds to the behavior of a known filter, already shown in FIGS. 2 and 3, is also shown in addition to curve N for the filter. By superimposing the two curves B and N, the advantages of the filters become particularly clear. FIG. 7B shows the substantially improved passband of the filter, which is shown here in enlarged scale.

FIG. 7C shows the corresponding Smith chart, where, on the left, the scatter parameter S11 is shown, and on the right, the scatter parameter S22. Here, too, one can see on the measurement curve N that the “rings” of a filter are substantially smaller and thus are located more centrally that those of the known filter shown in curve B.

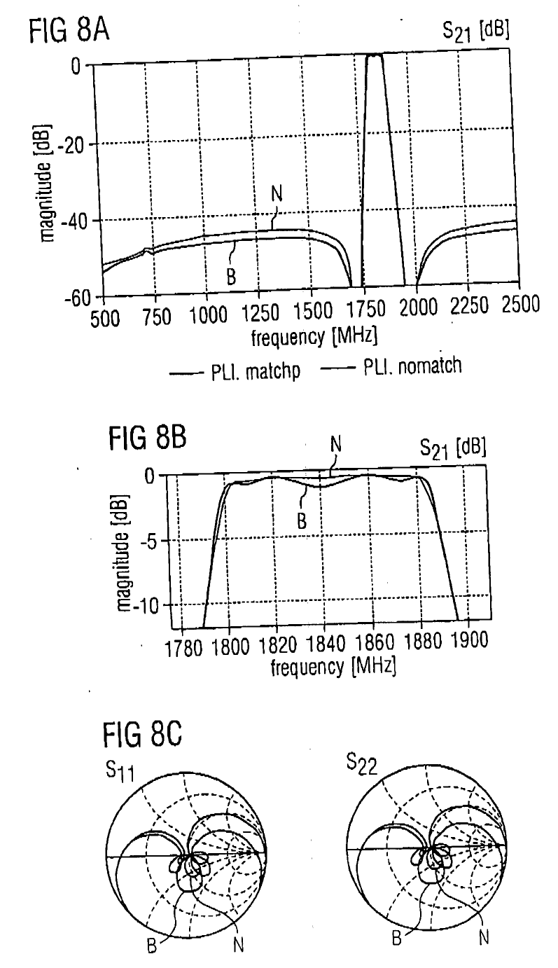

FIG. 8 shows that m is also designed equal to n equal to 0, and p equal to 2 in a filter, which is designed in accordance with FIG. 4B, and with its resonator arrangement designed in accordance with FIG. 5, with the corresponding parameters. Here, too, the measurement curves of the filter, designated with N, are contrasted with the measurement curve B of the already known filter. The advantageous characteristics of this filter are, in particular, shown in FIG. 8b, in the area of the flat passband, without an opening, and in FIG. 8C, wherein the latter shows particularly well the improved adaptation of the filter.

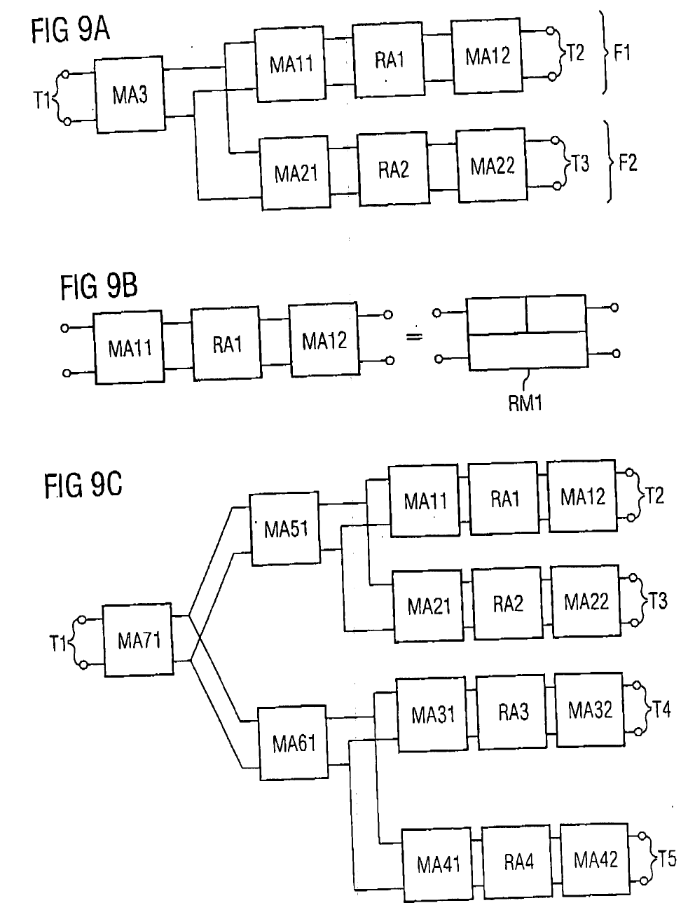

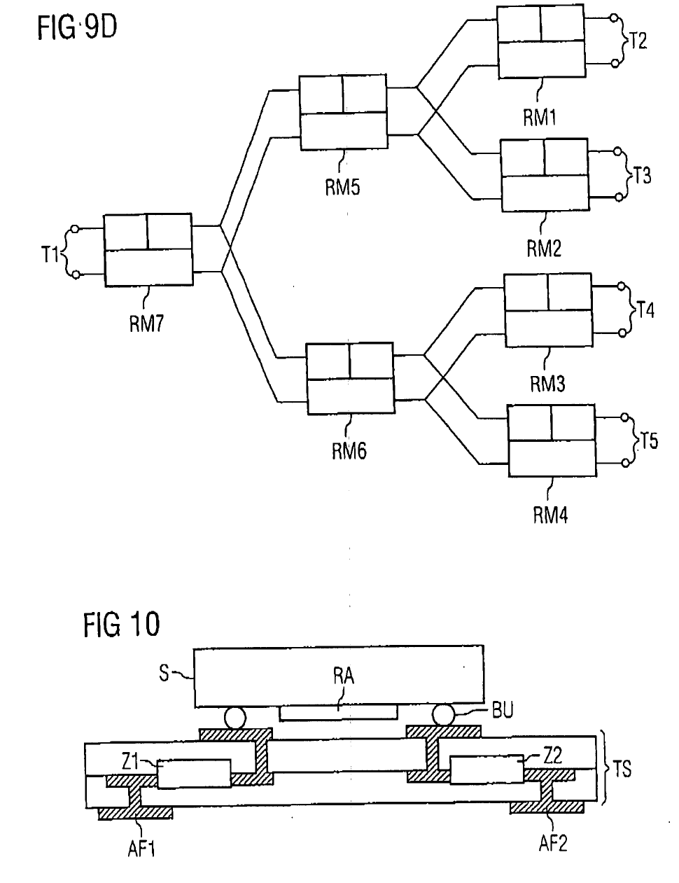

FIG. 9 shows a use of the filters in diplexer connections, which is particularly advantageous as a result of the improved electrical matching of the filters. Two filters F1, F2 are connected to one another in parallel in a diplexer according to FIG. 9A, wherein the first filter F1 connects the port T1 to the second port T2; the filter F2, on the other hand, connects the first port T1 to the third partial port T3. The two filters comprise resonator arrangements RA1, RA2 and are connected to complex impedances, which are shown in the figure as a matching unit MA. In one case a), for example, impedances arranged in series in the signal paths are provided, wherein for MA11 and MA21, the following are valid: r=1 and s=0. With MA3, r and s are equal to 0.

A possible case b) is similar; only here, for example, r and s are equal to 2 for the matching unit MA3 connected upstream.

A diplexer can be implemented particularly well from the parallel connection of two filters, since they are very well matched. By the good matching of filters, a cascade of filters, which corresponds in practice to a filter bank of a total of four filters, are implemented without disturbances between the individual filters. In this way, for example, it is possible to symmetrically diplex an input signal, in a purely passive manner, without a switch, to four reception filters (RX filters) in an end device for the mobile radio, wherein the four filter end stages can be correlated, for example, to the GSM bands GSM850, GSM900, GSM1800, and GSM 1900. The connection of the filters is carried out without additional switches by a direct connection, as shown, for example, in FIG. 9A.

FIG. 9C presents another cascade of filters, which connects an input port T1 to a total of four ports T2 to T5. The indices for the structural units according to FIG. 5 can be selected as follows in a concrete example.

| | MA11 = | MA21 = | RA1 = RA2 = | MA12 = MA22 = |
|---|---|---|---|---|
| | MA31 | MA41 | RA3 = RA4 | MA32 = MA42 |
| r | 1 | 0 | | 1 |
| s | 0 | 0 | | 0 |
| m = n = q | | | 0 | |
| p | | | 2 | |

FIG. 9B shows a simplified possibility of representing complex connections of filters, wherein a combined resonator/matching unit RM, whose indices can be selected arbitrarily within the indicated limits and can also amount to zero, results from resonator arrangement RA connected between two matching units MA1 and MA2. With the aid of this simplification, it is possible to give a simple description of, for example, a complex connection, as in FIG. 9D. The depicted cascade, comprised of 6 combined resonator/matching units RM, forms one input port, through two stages, into 4 output ports. The indices for the structural units can be selected as follows, in one concrete example, according to FIG. 5:

| | | r | s | m = n = q | p |
|---|---|---|---|---|---|
| RM7 | MA71 | 0 | 0 | | |
| | RA7 | | | 0 | 0 |
| | MA72 | 0 | 0 | | |
| RM5 = RM6 | MA51 = MA61 | 2 | 2 | | |
| | RA5 = RA6 | | | 0 | 0 |
| RM1 = RM3 | MA11 = MA31 | 1 | 0 | | |
| | RA1 = RA3 | | | 0 | 2 |
| | MA12 = MA32 | 1 | 0 | | |
| RM2 = RM4 | MA21 = MA41 | 0 | 0 | | |
| | RA2 = RA4 | | | 0 | 2 |
| | MA22 = MA42 | 1 | 0 | | |

The structure of FIG. 9C is obtained precisely with these variables.

It is also possible to continue this cascading via additional stages, wherein, in the general case, the cascading is carried out from x input ports to y output ports, where x, y are natural numbers and x<y.

FIG. 10 shows another development with the aid of a schematic cross section through an arrangement in which the bulk acoustic wave resonators are situated or produced on a substrate with the desired symmetrical resonator arrangement. The substrate S is connected in a flip chip construction mode via bumps BU to a carrier substrate TS. The carrier substrate TS has several dielectric layers, wherein metallization planes structured to printed conductor and connection structures are provided on, under, and between the layers. In this way, it is possible to implement connection structures on or in the carrier substrate, and in particular, to integrate the complex impedance in the interior of the carrier substrate TS. In the depicted cross section, two impedances Z1, Z2, for example, can be seen, which are connected in series in an electrical signal path between the resonator arrangement RA and a terminal surface AF, situated on the underside of the carrier substrate TS. The two terminal surfaces AF1, AF2 can be correlated, for example, to one of the electric ports of the filter.

If the complex impedance is designed, for example, as an inductor, the entire structure is advantageously considered in the dimensioning of the inductor, since the contacts and conductor sections implemented in the carrier substrate are themselves affected by the inductor, which contributes to the total inductance between the resonator arrangement RA and the terminal surface AF. The complex impedance, which is optimal for a filter, is then produced from the sum of the impedances of the individual connection structures or connection components and the concrete impedance elements Z, which are constructed in the interior of the carrier substrate, in addition to the conductors present. If these impedances are incorporated in series into the signal path and implemented as an inductor, then inductors between 0.1 and 10 nH at 2 GHz are sufficient for a matching filter operating in an approximately 100 Ohm environment, wherein at least the lower inductor values can already be implemented with bumps and the contacts and printed conductor sections shown, for example, in FIG. 10. Inductors connected in parallel, used as complex impedances, require higher inductance and are therefore may be designed as concrete structures with impedance, for example, as coils or meandering printed conductor sections.

Since it was only possible to illustrate a few embodiment examples, the scope of coverage is not restricted to them. The complex impedances which were not shown in more detail can represent, in the simplest case, inductors; in an actual embodiment however, they can represent any combination of connected different circuit elements with impedance. The bulk acoustic wave resonators can be constructed in a known manner, for example, as FBAR resonators. The type and number of substructures used in a resonator arrangement can be selected arbitrarily. Furthermore, the impedances can also be implemented on the surface of the substrate, on the surface of the carrier substrate, or as concrete components outside the arrangement, as shown, for example, in FIG. 10.

Although the filters described herein can be operated symmetrically, this does not rule out asymmetrical operation on one or both sides. Such filters can then be operated, for example, balanced/unbalanced. With such a mode of operation, nothing is changed in the advantageous filter behavior of the filters.

What is claimed is:

1. A filter for use with bulk acoustic waves, comprising:
an input port and an output port, the input port and the output port being symmetrically operable;
signal paths that extend from a terminal of the input port to a terminal of the output port;
bulk acoustic wave resonator in the signal paths, the bulk acoustic wave resonators being arranged symmetrically in the signal paths; and
a complex impedance associated with each signal path for electrically matching to a corresponding connection.

2. The filter of claim 1, wherein terminals of at least of the input port and the output port are electrically connected to a complex impedance.

3. The filter of claim 1, wherein a complex impedance associated with each signal path is in series in each signal path.

4. The filter of claim 1, wherein a complex impedance associated with each signal path electrically connects one signal path to another signal path.

5. The filter of claim 1, wherein terminals of at least one of the input port and the output port are bridged with a transverse branch comprising a complex impedance.

6. The filter of claim 1, wherein a terminal of at least of the input port and the output port is electrically connected to ground via a transverse branch comprising a complex impedance.

7. The filter of claim 1, wherein terminals of one of the input port and the output port, are in series to a complex impedance; and
wherein terminals of one of the input port and the output port are in parallel with a complex impedance.

8. The filter of claim 1, wherein at least some of the bulk acoustic wave resonators are in a ladder-type arrangement.

9. The filter of claim 1, wherein at least some of the bulk acoustic wave resonators are in a lattice arrangement.

10. The filter of claim 1, wherein at least some of the bulk acoustic wave resonators are in a stacked resonator arrangement or a coupled resonator filter (CRF) arrangement.

11. The filter of claim 1, wherein the bulk acoustic wave resonators comprise at least two substructures comprised of bulk acoustic wave resonators, the at least two substructures being in series, and wherein bulk acoustic wave resonators in the substructures are in a ladder-type arrangement, a lattice arrangement, or a coupled resonator filter (CRF) arrangement.

12. The filter of claim 1, wherein the complex impedance comprises an inductor.

13. The filter of claim 1, wherein the bulk acoustic wave resonators are on a common substrate of a carrier; and
wherein circuit structures and passive components comprising complex impedances are in the carrier.

14. The filter of claim 1:
wherein the bulk acoustic wave resonators are on a common substrate produced from a semiconductor wafer; and
further comprising complex impedances are at least partially integrated with the common substrate.

15. The filter of claim 1 having a balanced connection at a first port and an unbalanced connection at a second port.

16. The filter of claim 1, wherein the filter comprises at least one coupled resonator filter (CRF), the at least one CRF filter comprising:
a stack comprising:
at least one first bulk acoustic wave resonator;
a coupling layer; and
a second bulk acoustic wave resonator;
wherein two electrodes of the at least one first bulk acoustic wave resonator are electrically connected to a first port, and electrodes of the second bulk acoustic wave resonator are electrically connected to a second port.

17. The filter of claim 1 having an operating frequency in a range of 2 GHz;
wherein each signal path is in series with at least one complex impedance; and
wherein the at least one complex impedance comprises an inductor between 0.1 nH and 10.0 nH.

18. The filter of claim 4 having an operating frequency in a range of 2 GHz;
wherein two signal paths are in parallel with a complex impedance comprising an inductor between 10 nH and 100 nH.

19. A diplexer comprising the filter of claim 1.

20. A cascade of filters comprising the filter of claim 1.

21. A filter for use with bulk acoustic waves, comprising:
a first bulk acoustic wave resonator;
a second bulk acoustic wave resonator;
a coupling layer between the first bulk acoustic wave resonator and the second bulk acoustic wave resonator, the first bulk acoustic wave resonator and the second bulk acoustic wave resonator being symmetric relative to the coupling layer;
a first electrode layer electrically connected to a first signal path of a first port, the first electrode layer being adjacent to the first bulk acoustic wave resonator;
a second electrode layer electrically connected to a second signal path of a first port, the second electrode layer being between the first bulk acoustic wave resonator and the coupling layer;
a third electrode layer electrically connected to a first signal path of a second port, the third electrode layer being adjacent to the second bulk acoustic wave resonator, and
a fourth electrode layer electrically connected to a second signal path of the second port, the fourth electrode layer being between the second bulk acoustic wave resonator and the coupling layer; and
complex impedances associated with the first and second signal paths of the first and second ports for matching to impedances of external connections.

22. The filter of claim 21, wherein the first bulk acoustic wave resonator and the second bulk acoustic wave resonator are acoustically coupled.

23. A diplexer comprising:
a first filter for use with bulk acoustic waves;
a first complex impedance at an input port of the first filter;
a second complex impedance at an output port of the first filter;
a second filter for use with bulk acoustic waves;
a third complex impedance at an input port of the second filter;
a fourth complex impedance at an output port of the second filter;
wherein the first filter and the second filter are connected in parallel via at least one fifth complex impedance; and
wherein each of the first filter and second filter comprises:
signal paths that extend from an input port to an output port, and
bulk acoustic wave resonators arranged symmetrically in the signal paths.
